(19) United States
(12) Patent Application Publication
(10) Pub. No.: US 2009/0211630 A1
(43) Pub. Date: Aug. 27, 2009

(54) DYE-SENSITIZED SOLAR CELL AND METHOD OF MANUFACTURING THE SAME

(75) Inventors: Hogyeong YUN, Seoul (KR); Yongseok Jun, Daejeon-city (KR); Mangu Kang, Daejeon-city (KR); Hunkyun Pak, Daejeon-city (KR); Jong Hyeok Park, Daejeon-city (KR); Seungyup Lee, Gyeongsangbuk-Do (KR); Jongdae Kim, Daejeon-city (KR)

Correspondence Address: RABIN & Berdo, PC, 1101 14TH STREET, NW, SUITE 500, WASHINGTON, DC, 20005, US

(73) Assignee: ELECTRONICS AND TELECOMUNICATIONS RESEARCH INSTITUTE, Daejeon-city (KR)

(21) Appl. No.: 12/336,265

(22) Filed: Dec. 16, 2008

(30) Foreign Application Priority Data
Dec. 17, 2007 (KR) 10-2007-0132642

(51) Int. Cl. H01L 31/00; H01L 21/20

(52) U.S. Cl. 136/256; 438/85; 257/E21.09; 977/932

(57) ABSTRACT

Provided are a dye-sensitized solar cell and a method of manufacturing the same. The dye-sensitized solar cell includes a semiconductor electrode and a counter electrode that face each other, and an electrolytic solution interposed therebetween, wherein the semiconductor electrode includes: a conductive substrate; an oxide semiconductor-conductor structure formed on the conductive substrate; and dye molecules layer adsorbed onto the surface of the oxide semiconductor. A dye-sensitized solar cell manufactured using the method can effectively prevent electrons transferred to the conductor and an electrolyte from recombining, thus having maximal photoelectron conversion efficiency.

### CROSS-REFERENCE TO RELATED PATENT APPLICATION

This application claims the benefit of Korean Patent Application No. 10-2007-0132642, filed on Dec. 17, 2007, in the Korean Intellectual Property Office, the disclosure of which is incorporated herein in its entirety by reference.

### BACKGROUND OF THE INVENTION

1. Field of the Invention

The present invention relates to a dye-sensitized solar cell and a method of manufacturing the same, and more particularly, to a dye-sensitized solar cell which can effectively prevent transferred electrons and an electrolyte from recombining, thus having maximal photoelectron conversion efficiency, and a method of manufacturing the same. The work was supported by the IT R&D program of MIC/IITA [2006-S-006-02, Components/Module technology for Ubiquitous Terminals].

2. Description of the Related Art

Unlike wafer-type silicon solar cells using p-n junction or compound solar cells, dye-sensitized solar cells are photo-electrochemical solar cells that primarily comprise photosensitive dye molecules capable of generating electron-hole pairs by absorbing incident light having a wavelength of visible light, semiconductor oxides capable of receiving excited electrons, and an electrolyte that reacts with electrons transported back after performing electrical work in an external circuit. Gratzel cells disclosed in U.S. Pat. Nos. 4,927,721 and 5,350,644, issued to Gratzel et al. (Switzerland) are representative dye-sensitized solar cells. These dye-sensitized solar cells include an oxide semiconductor electrode formed of a nanoparticle titanium dioxide (TiO₂) onto which dye molecules are adsorbed, a counter electrode coated with platinum or carbon, and an electrolytic solution filled between the oxide semiconductor electrode and the counter electrode. These photo-electrochemical solar cells can be manufactured at lower costs per unit of power, as compared with wafer-type silicon solar cells using p-n junctions, and thus have attracted widespread interest.

The principle of operation of a dye-sensitized solar cell will now be explained. Electrons from photosensitive dyes excited by sunlight are injected into a conduction band of the nanoparticle TiO₂. The injected electrons pass through the nanoparticle TiO₂ to reach a conductive substrate and are transferred to an external circuit. After performing electrical work in the external circuit, the electrons are transferred back into the nanoparticle TiO₂ through the counter electrode by an oxidation/reduction electrolyte so as to reduce photosensitive dyes having insufficient electrons, thereby completing the operation of the dye-sensitized solar cell.

Here, when the electrons injected from the photosensitive dyes pass through the nanoparticle TiO₂ layer and the conductive substrate before reaching the external circuit, some of the injected electrons may remain in an empty surface energy level on the surface of the nanoparticle TiO₂ layer. In this case, the electrons react with the oxidation/reduction electrolyte, and are removed inefficiently instead of moving through the circuit. In addition, the electrons generated by light may also react with the oxidation/reduction electrolyte and may be lost on the surface of the conductive substrate, thereby decreasing energy conversion efficiency. FIG. 6 is a partial cross-sectional view of a conventional dye-sensitized solar cell, wherein a portion of a semiconductor electrode of the dye-sensitized solar cell is exaggeratedly expanded. In particular, as shown in FIG. 6, electrons injected into the TiO₂ layer from dyes may recombine with the electrolyte, thus being lost before reaching a conductor.

Photoelectron energy conversion efficiency is determined by multiplying current by voltage by fill factor. Thus, in order to improve the photoelectron energy conversion efficiency, values of the current, voltage and fill factor should be increased. A method of maximizing the voltage involves maximizing the density of electrons in an oxide semiconductor by minimizing recombination between electrons and the electrolyte. A variety of research into the method described above has been conducted, but there is still a need for improvement.

### SUMMARY OF THE INVENTION

The present invention provides a dye-sensitized solar cell which can effectively prevent an electrolyte and electrons transferred to a conductor from recombining by minimizing a path of electrons, thus having maximal photoelectron conversion efficiency.

The present invention also provides a method of manufacturing a dye-sensitized solar cell which can effectively prevent an electrolyte and electrons transferred to a conductor from recombining by minimizing a path of electrons, thus having maximal photoelectron conversion efficiency.

The present invention also provides an electrical device including the dye-sensitized solar cell.

According to an aspect of the present invention, there is provided a dye-sensitized solar cell comprising a semiconductor electrode and a counter electrode that face each other, and an electrolytic solution interposed therebetween, wherein the semiconductor electrode comprises: a conductive substrate; an oxide semiconductor-conductor structure formed on the conductive substrate, comprising an oxide semiconductor and a conductor; and dye molecules adsorbed onto the surface of the oxide semiconductor.

The oxide semiconductor-conductor structure may be a structure in which the conductor in the form of a nanostructure formed on the conductive substrate is electrically connected to the conductive substrate, and the oxide semiconductor is coated on the surface of the conductor. The nanostructure may comprise one selected from the group consisting of nanoparticles, nanotubes, nanorods, nanohorns, nanospheres, nanofibers, nanorings, and nanobelts.

The thickness of the oxide semiconductor coated on the surface of the conductor may be in a range of about 0.1 to about 50 nm.

According to another aspect of the present invention, there is provided a method of manufacturing a dye-sensitized solar cell, comprising: forming a semiconductor electrode; forming a counter electrode; disposing the semiconductor electrode and the counter electrode to face each other; and injecting an electrolytic solution between the semiconductor electrode and the counter electrode, wherein the forming of the semiconductor electrode comprises: providing a conductive substrate; forming an oxide semiconductor-conductor structure on the conductive substrate; and adsorbing dye molecules layer onto the surface of the oxide semiconductor-conductor structure.

The forming of the oxide semiconductor-conductor structure on the conductive substrate may comprise: forming a conductor on the conductive substrate; and forming an oxide semiconductor layer on the surface of the conductor.

The forming of the oxide semiconductor layer on the surface of the conductor may comprise: dissolving a metal, an organic metallic compound, or an inorganic metallic compound in a solvent to prepare a slurry of the metal, the organic metallic compound, or the inorganic metallic compound; forming a layer of the slurry on the surface of the conductor; and heat treating the conductor on which the layer formed of the slurry is formed.

According to another aspect of the present invention, there is provided an electrical device comprising the dye-sensitized solar cell.

The dye-sensitized solar cell manufactured by the method can effectively prevent electrons transferred to the conductor and an electrolyte from recombining, thus having maximal photoelectron conversion efficiency.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a main structure of a dye-sensitized solar cell according to an embodiment of the present invention;

FIG. 2 is a partial cross-sectional view of the dye-sensitized solar cell of FIG. 1, wherein a portion of a semiconductor electrode of the dye-sensitized solar cell is exaggeratedly expanded;

FIGS. 3 and 4 are respectively partial cross-sectional views of dye-sensitized solar cells according to other embodiments of the present invention, wherein portions of semiconductor electrodes of the dye-sensitized solar cells are exaggeratedly expanded;

FIG. 5 is a flowchart illustrating a method of manufacturing a dye-sensitized solar cell, according to an embodiment of the present invention; and

FIG. 6 is a partial cross-sectional view of a conventional dye-sensitized solar cell, wherein a portion of a semiconductor electrode of the dye-sensitized solar cell is exaggeratedly expanded.

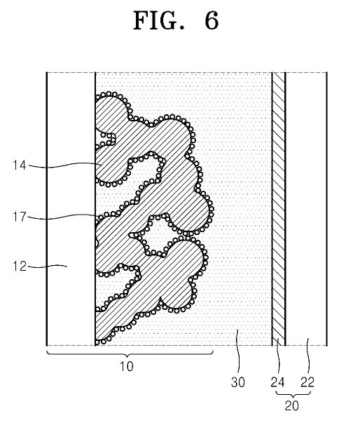

### DETAILED DESCRIPTION OF THE INVENTION

Hereinafter, exemplary embodiments of the present invention will be described in more detail with reference to the accompanying drawings.

Exemplary embodiments of the present invention may be embodied in many different forms and should not be construed as being limited to embodiments set forth herein. Rather, these embodiments are provided so that this disclosure will be thorough and complete. In the present specification, it will be understand that when a layer is referred to as being “on” another layer or substrate, it can be directly on the other layer or substrate, or intervening layers may also be present. In the accompanying drawings, thicknesses and sizes of layers and regions are exaggerated for clarity. Thus, the present invention is not limited to the relative sizes or intervals shown in the accompanying drawings. The same reference numerals refer to the same constitutional elements throughout the drawings.

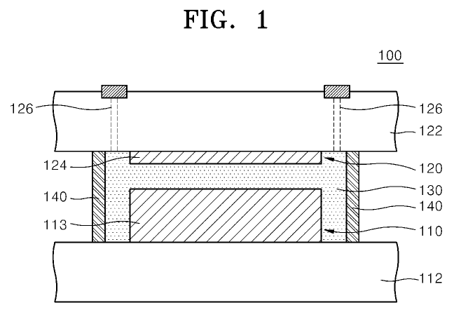

FIG. 1 is a cross-sectional view illustrating a main structure of a dye-sensitized solar cell 100 according to an embodiment of the present invention.

Referring to FIG. 1, the dye-sensitized solar cell 100 according to the current embodiment of the present invention includes a semiconductor electrode 110 and a counter electrode 120 that face each other, and an electrolyte layer 130 interposed between the semiconductor electrode 110 and the counter electrode 120.

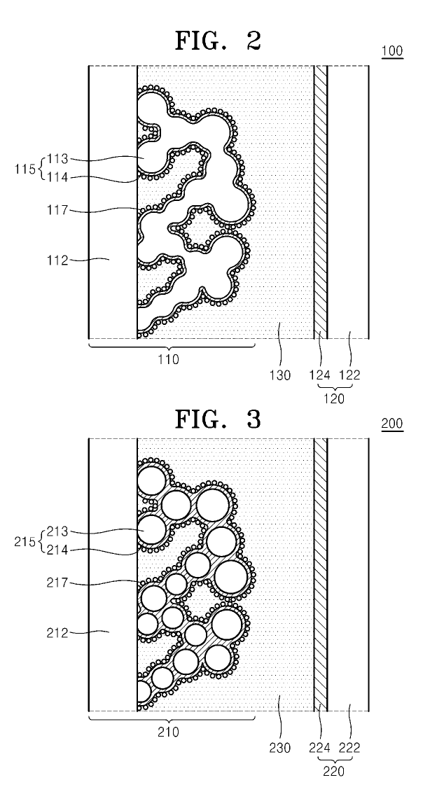

FIG. 2 is a partial cross-section view of the dye-sensitized solar cell 100 of FIG. 1, wherein a portion of the semiconductor electrode 110 of the dye-sensitized solar cell 100 is exaggeratedly expanded.

Referring to FIG. 2, the semiconductor electrode 110 includes a conductive substrate 112, and an oxide semiconductor-conductor structure 115 formed on the conductive substrate 112, wherein the oxide semiconductor-conductor structure 115 includes a conductor 113, an oxide semiconductor 114 formed on the conductor 113, and dye molecules layer 117 adsorbed on the surface of the oxide semiconductor 114.

The conductive substrate 112 may be formed of, for example, indium tin oxide (ITO), indium zinc oxide (IZO), fluorine-doped tin oxide (FTO), ZnO—Ga₂O₃, ZnO—Al₂O₃, SnO₂—Sb₂O₃, or the like, or may be a glass substrate of which surface is coated with SnO₂. However, the present invention is not limited to the above examples.

The conductive substrate 112 may be electrically connected to the oxide semiconductor-conductor structure 115. In particular, the conductor 113 of the oxide semiconductor-conductor structure 115 may be electrically connected to the conductive substrate 112. The conductor 113 may be formed of any conductive material without limitation. In particular, the conductor 113 may be formed of a carbon-based material, a metal, a conductive polymer, or a conductor-doped oxide; however, the present invention is not limited thereto.

Examples of the carbon-based material may include carbon powder, graphite, fullerene (C₆₀), carbon black, acetylene black, activated carbon, carbon nanotubes, carbon nanofibers, carbon nanowires, carbon nanospheres, carbon nanohorns, carbon nanorings, carbon nanorods, carbon nanobelts, and the like.

The metal may be any metal that is in a solid state at room temperature.

The conductive polymer may be a polyaniline-based polymer, a polyacetylene-based polymer, a polypyrrole-based polymer, or a polythiophene-based polymer.

The conductor-doped oxide may be an oxide, such as silicon oxide, zinc oxide, titanium oxide, or the like that is doped with n-type dopant. Types of elements that act as the n-type dopant for each oxide are well known in the art, and thus a detailed description thereof is not provided here.

The conductive substrate 112 and the conductor 113 may be formed of the same material or different materials from each other.

As illustrated in FIG. 2, the oxide semiconductor-conductor structure 115 may be formed by electrically connecting a plurality of particles of the conductor 113 with each other and coating the oxide semiconductor 114 on the surface of the conductor 113. In order for electrons excited by light to be transferred to the conductor 113 from the dye molecules 117 that are adsorbed onto the surface of the oxide semiconductor 114, it is necessary that the electrons move by only a length corresponding to the thickness of the oxide semiconductor 114, which is relatively thin. As a result, a probability of recombination between the electrons transferred from the dye molecules 117 and the electrolyte in the electrolyte layer 130 decreases significantly. Thus, the density of electrons in the oxide semiconductor 114 can be maximized, and a voltage increase is obtained therefrom. Ultimately, photoelectron energy conversion efficiency can be improved.

The type of the oxide semiconductor-conductor structure 115 is not particularly limited, and as illustrated in FIG. 2, may be irregular. However, the oxide semiconductor-conductor structure 115 may be in a nanostructure form, such as nanoparticles, nanotubes, nanorods, nanohorns, nanospheres, nanofibers, nanorings, or nanobelts.

In particular, the size of the nanostructure may be in a range of 1 to 1000 nm. Herein, the size of the nanostructure is defined as a distance between two points farthest away from each other in particles constituting the nanostructure.

The oxide semiconductor 114 is thinly coated on the conductor 113. The coated thickness of the oxide semiconductor 114 may be in a range of 0.1 to 50 nm. That is, a distance in which electrons should move in order to be transferred up to the conductor 113 is decreased by a factor of ten to several hundred thousand compared with the prior art. Thus, a probability of recombination of the electrons and the electrolyte also decreases in proportional to the decrease of the distance.

The oxide semiconductor 114 may comprise titanium dioxide (TiO₂), tin dioxide (SnO₂), zinc oxide (ZnO), tungsten oxide (WO₃), niobium oxide (Nb₂O₅), titanium strontium oxide (TiSrO₃) or a combination thereof. In particular, the oxide semiconductor 114 may comprises titanium dioxide in an anatase form.

The dye molecules 117 coated on the oxide semiconductor 114 may be any dye molecules that are commonly used in solar cells without limitation, that have charge separation functions, and that can be photosensitive. The dye can be, for example, a ruthenium complex, a xanthine based dye such as rhodamine B, Rose Bengal, eosin, or erythrosine; a cyanine based dye such as quinocyanin or cryptocyanine; a basic dye such as phenosafranine, capri blue, thiosine, or methylene blue; a porphyrin based compound such as chlorophyll, zinc porphyrin, or magnesium porphyrin; an azo dye; a phthalocyanine compound; a ruthenium tris-bipyridyl based complex compound; an anthraquinone based dye; a polycyclic quinone based dye; and a single or a mixture of at least two of the above materials can be used as the dye. In particular, the ruthenium complex can be RuL₂(SCN)₂, RuL₂(H₂O)₂, RuL₃, or RuL₂ wherein L can be 2,2′-bipyridyl-4,4′-dicarboxylate.

The electrolyte layer 130 may include an imidazole-based compound and iodine. For example, the electrolyte layer 130 can be a layer in which an iodine-based oxidation-reduction electrolyte (I⁻/I₃⁻) is dissolved. The electrolyte layer 130 may include an electrolytic solution obtained by dissolving 0.70 M of 1-vinyl-3-methyl-imidazolium iodide, 0.10 M of Lil, 40 mM of I₂ and 0.125 M of 4-tert-butylpyridine in 3-methoxypropionitrile.

The counter electrode 120 may include an electrically conductive substrate 122 and a metallic layer 124 coated on the electrically conductive substrate 122. In particular, the metallic layer 124 may be, for example, a platinum layer. In addition, the electrically conductive substrate 122 may be formed of ITO or FTO, or may be a glass substrate of which surface is coated with tin oxide.

The metallic layer 124 of the counter electrode 120 may be disposed to face the semiconductor electrode 110.

The operation of the dye-sensitized solar cell 100 according to the current embodiment of the present invention and as illustrated in FIGS. 1 and 2, will now be described.

When light that is transmitted through the conductive substrate 112 of the semiconductor electrode 110 reaches the dye molecules 117 adsorbed onto the oxide semiconductor 114, the dye molecules 117 are excited. As a result, electrons are injected into a conduction band of the oxide semiconductor 114. The electrons injected into the oxide semiconductor 114 can be easily transferred to the conductor 113 coated by the oxide semiconductor 114, and then are transferred to an external circuit (not shown) via the conductive substrate 112. The electrons that perform electrical work in the external circuit (not shown) are transferred to the counter electrode 120.

The dye molecules 117 oxidized as a result of the electron transition receive electrons provided by oxidation and reduction (3I⁻→I₃⁻+2e⁻) of iodine ions in the electrolyte layer 130, and are reduced. Herein, the oxidized iodine ions (I₃⁻) are reduced again by electrons that reach the counter electrode 120. As a result, the operation of the dye-sensitized solar cell 100 is completed.

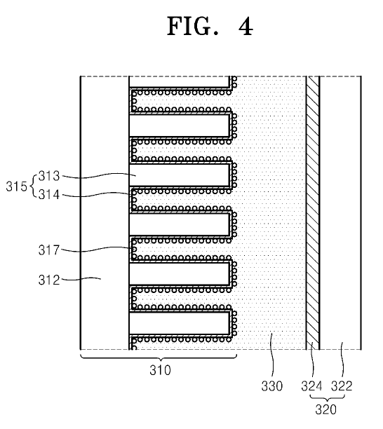

FIG. 3 is a partial cross-sectional view of a dye-sensitized solar cell 200 according to another embodiment of the present invention. Unlike in the dye-sensitized solar cell 100 of FIG. 2, in terms of forming an oxide semiconductor-conductor structure 215 of the dye-sensitized solar cell 200 of FIG. 3, conductors 213 do not directly contact each other, but are connected by an oxide semiconductor 214.

Comparing the configuration of FIG. 3 with the configuration of FIG. 2, cell efficiency of the dye-sensitized solar cell 200 is a little lower. However, in terms of a method of manufacturing the dye-sensitized solar cell 200, which is to be described later, each conductor particle is coated by an oxide semiconductor, and then the conductors coated by the oxide semiconductor are formed on a conductive substrate. Therefore, a manufacturing process is simple, and the dye-sensitized solar cell 200 is suitable for mass-production.

FIG. 4 is a partial cross-sectional view of a dye-sensitized solar cell 300 according to another embodiment of the present invention. Referring to FIG. 4, conductors 313 are in the form of nanorods, nanowires, or nanotubes. Thus the conductors 313 can have a wider surface area, and accordingly, high cell efficiency can be obtained.

As described above, the semiconductor electrodes 110, 210 and 310 are respectively constituted such that the oxide semiconductors 114, 214 and 314 are respectively coated on the conductors 113, 213 and 313. Thus, in terms of the operation process of the dye-sensitized solar cells 100, 200 and 300 according to the embodiments of the present invention, a path in which the electrons transferred from the dye molecules 117, 217 and 317 are transferred to the conductors 113, 213 and 313 becomes significantly shorter compared with the prior art. Thus, recombination between the electrolyte in the electrolyte layers 130, 230 and 330 and the electrons transferred from the dye molecules 117, 217 and 317 after being excited can be minimized. As a result, photoelectron conversion efficiency can be maximized.

The dye-sensitized solar cells described above can be applied in a variety of electrical devices, for example, portable electronic devices, such as power suppliers for home, automobiles, ships, airplanes, traffic lights, outdoor advertisements, mobile phones, and MP3 players. In addition, the dye-sensitized solar cells may be applied in industrial equipment; however, the present invention is not limited to the above examples.

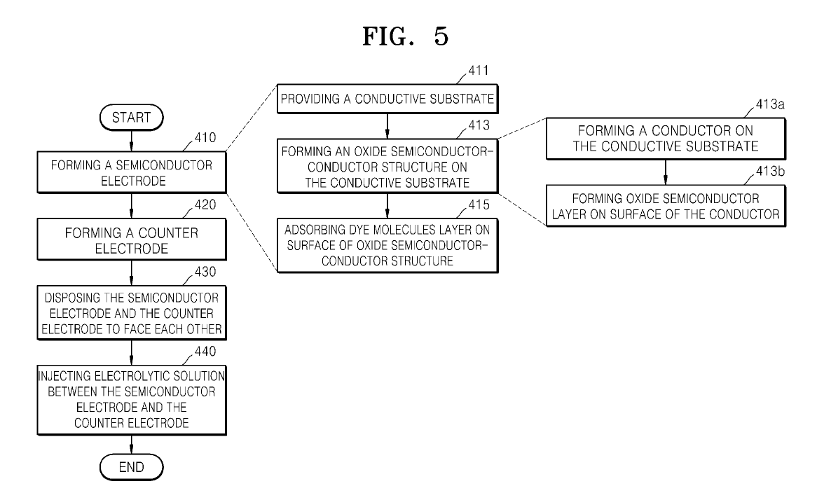

FIG. 5 is a flowchart illustrating a method of manufacturing a dye-sensitized solar cell, according to an embodiment of the present invention.

Referring to FIGS. 1 through 5, the semiconductor electrode 110, 210 or 310 is formed in operation 410. The counter electrode 120, 220 or 320 is formed in operation 420. The semiconductor electrode 110, 210 or 310 and the counter electrode 120, 220 or 320 are disposed to face each other in operation 430. Then, in operation 440, an electrolytic solution is injected between the semiconductor electrode 110, 210 or 310 and the counter electrode 120, 220 or 320 to form the electrolyte layer 130, 230 or 330. In FIG. 5, operation 410 is followed by operation 420. However, operations 410 and 420 can be performed regardless of the order, and may also be performed simultaneously.

Each operation will be described in more detail. Operation 410 may include: providing a conductive substrate (operation 411); forming an oxide semiconductor-conductor structure on the conductive substrate (operation 413); and adsorbing dye molecules onto the surface of the oxide semiconductor-conductor structure (operation 415).

The conductive substrate may be a substrate having configurations as described above, and thus a detailed description thereof is not provided here.

The forming of the oxide semiconductor-conductor structure on the conductive substrate may include: forming a conductor on the conductive substrate (operation 413a); and forming a layer formed of an oxide semiconductor on the surface of the conductor (operation 413b).

The forming of the conductor on the conductive substrate may be performed in such a manner that the conductor is deposited on the conductive substrate by, for example, chemical vapor deposition (CVD), sputtering, sintering, electroplating, spraying, or coating. Herein, these methods may be selectively used according to the type of the conductors. Coating may be used for conductive polymers, CVD, spraying, or coating may be used for carbon-based materials. In addition, sputtering, electroplating, or sintering may be used for metals. In addition, in the case of conductor-doped oxides, an oxide layer is formed by CVD or sputtering, and then a dopant is ion-implanted thereinto.

The forming of the layer formed of the oxide semiconductor on the surface of the conductor may be performed by directly coating the oxide semiconductor on the surface of the conductor. Herein, the layer formed of the oxide semiconductor may be formed of a material, such as TiO₂, SnO₂, ZnO, or MgO.

Optionally, the forming of the layer formed of the oxide semiconductor on the surface of the conductor may be performed by preparing a slurry of a metal or a metal precursor, coating the slurry on the surface of the conductor, and then heat treating the resultant to oxidize the metal or metal precursor.

That is, a metal, such as Ti, Sn, Zn, Mg, or the like, or an organic or inorganic metallic compound thereof is dissolved in a solvent to prepare the slurry of the metal or metal precursor. The solvent is not particularly limited, but may be water, an alcohol-based solvent, such as methanol, ethanol, isopropylalcohol, n-propylalcohol, or butylalcohol, dimethylacetamide (DMAc), dimethylformamide, dimethylsulfoxide (DMSO), N-methylpyrrolidone, tetrahydrofurane, or the like.

The coating of the slurry on the surface of the conductor may be performed by screen printing, spray coating, coating using a doctor blade, gravure coating, dip coating, silk screening, painting, or the like, but the present invention is not limited thereto. In addition, the conductor may be immersed into the slurry for at least 12 hours.

The heat treating of the resultant may be performed at a temperature in a range of 100° C. to 800° C. for several minutes to several hours in an air or oxidizing atmosphere. When the heat treatment is performed at less than 100° C. or for less than several minutes, the solvent is insufficiently removed, and the heat treated resultant is not sufficiently formed as an oxide. In addition, when the heat treatment is performed at a temperature greater than 800° C. or for an excessively long time, particles are excessively sintered, and thus the surface area may decrease significantly.

Hereinbefore, the forming of the oxide semiconductor layer on the conductor after the forming of the conductor on the conductive substrate has been described. However, a conductor coated with an oxide semiconductor may be first prepared, and then the oxide semiconductor-conductor structure may be formed on the conductive substrate using the conductor coated with the oxide semiconductor.

The preparation of the conductor coated with the oxide semiconductor may be performed, as described above, by directly coating the oxide semiconductor on the surface of the conductor, or by preparing the slurry of the metal or metal precursor, coating the slurry on the surface of the conductor, and then heat treating the resultant to oxidize the metal or metal precursor.

After the preparation of the conductor coated with the oxide semiconductor, the conductor may be dispersed in a dispersion medium to prepare a slurry or paste, the slurry or paste may be coated on the conductive substrate, and then the dispersion medium may be removed. The dispersion medium may be, but is not limited to, the solvent as described above.

In operation 420, the counter electrode 120, 220 or 320 may be formed by forming the metallic layer 124, 224 or 324 on the electrically conductive substrate 122, 222 or 322. The metallic layer 124, 224 and 324 may be, for example, a platinum layer.

In operation 430, the semiconductor electrode 110, 210 or 310 is disposed to face the counter electrode 120, 220 or 320. For this, polymer layers that comprise, for example, SURLYN® (Product name, manufactured by Du Pont) and have a thickness of about 30 to 50 μm are disposed between the conductive substrate 112, 212 or 312 and the electrically conductive substrate 122, 222 or 322. Then, the two substrates are pressed together on a hot plate at about 100 to 140° C., at about 1 atm to about 3 atm. As a result, the polymer layers are strongly adhered to the surfaces of the two electrodes due to the applied heat and pressure.

In operation 440, an electrolytic solution is injected into a space between the two electrodes. After the space is filled with the electrolytic solution, the polymer layers and the substrates are instantaneously heated to seal an inlet.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A dye-sensitized solar cell comprising a semiconductor electrode and a counter electrode that face each other, and an electrolytic solution interposed therebetween,
wherein the semiconductor electrode comprises:
a conductive substrate;
an oxide semiconductor-conductor structure formed on the conductive substrate; and
dye molecules layer adsorbed onto the surface of the oxide semiconductor.

2. The dye-sensitized solar cell of claim 1, wherein the oxide semiconductor-conductor structure is a structure in which the conductor in the form of a nanostructure formed on the conductive substrate is electrically connected to the conductive substrate, and the oxide semiconductor is coated on the surface of the conductor.

3. The dye-sensitized solar cell of claim 2, wherein the nanostructure comprises one selected from the group consisting of nanoparticles, nanotubes, nanorods, nanohorns, nanospheres, nanofibers, nanorings, and nanobelts.

4. The dye-sensitized solar cell of claim 2, wherein the size of the nanostructure is in a range of 1 nm to 1000 nm.

5. The dye-sensitized solar cell of claim 2, wherein the thickness of the oxide semiconductor coated on the surface of the conductor is in a range of 0.1 to 50 nm.

6. The dye-sensitized solar cell of claim 1, wherein the conductor comprises a carbon-based material, a doped oxide, a metal, or a conductive polymer.

7. The dye-sensitized solar cell of claim 2, wherein the oxide semiconductor-conductor structure is a structure in which conductor particles coated with the oxide semiconductor are connected to each other.

8. A method of manufacturing a dye-sensitized solar cell, comprising:
forming a semiconductor electrode;
forming a counter electrode;
disposing the semiconductor electrode and the counter electrode to face each other; and
injecting an electrolytic solution between the semiconductor electrode and the counter electrode,
wherein the forming of the semiconductor electrode comprises:
providing a conductive substrate;
forming an oxide semiconductor-conductor structure on the conductive substrate; and
adsorbing dye molecules layer onto the surface of the oxide semiconductor-conductor structure.

9. The method of claim 8, wherein the forming of the oxide semiconductor-conductor structure on the conductive substrate comprises: forming a conductor on the conductive substrate; and forming a layer of the oxide semiconductor on the surface of the conductor.

10. The method of claim 9, wherein the conductor comprises a carbon-based material, a doped oxide, a metal, or a conductive polymer.

11. The method of claim 9, wherein the forming of the conductor on the conductive substrate comprises depositing the conductor on the conductive substrate using a method selected from the group consisting of chemical vapor deposition, sputtering, sintering, electroplating, spraying, and coating.

12. The method of claim 9, wherein the forming of the layer of the oxide semiconductor on the surface of the conductor comprises coating the oxide semiconductor on the surface of the conductor.

13. The method of claim 9, wherein the forming of the layer of the oxide semiconductor on the surface of the conductor comprises:
dissolving a metal, an organic metallic compound, or an inorganic metallic compound in a solvent to prepare a slurry of the metal, the organic metallic compound, or the inorganic metallic compound;
forming a layer of the slurry on the surface of the conductor; and
heat treating the conductor on which the layer formed of the slurry is formed.

14. The method of claim 13, wherein the heat treatment is performed at a temperature of 100° C. to 350° C. in an air or oxidizing atmosphere.
